(19) United States
(12) Patent Application Publication
(10) Pub. No.: US 2015/0109024 A1
(43) Pub. Date: Apr. 23, 2015

(54) Field Programmable Gate-Array with Embedded Network-on-Chip Hardware and Design Flow

(71) Applicants: Mohamed Saied Abdelfattah, Toronto (CA); Vaughn Timothy Betz, Toronto (CA)

(72) Inventors: Mohamed Saied Abdelfattah, Toronto (CA); Vaughn Timothy Betz, Toronto (CA)

(73) Assignees: Vaughn Timothy Betz, Toronto (CA); Mohamed Saied Abdelfatah, Toronto (CA)

(21) Appl. No.: 14/060,253

(22) Filed: Oct. 22, 2013

(51) Int. Cl. G06F 17/50; H03K 19/0175

(52) U.S. Cl. CPC G06F 17/5054; H03K 19/017581
USPC 326/41; 716/116

(57) ABSTRACT

An enhanced field programmable gate-array (FPGA) incorporates one or more programmable networks-on-chip (NoCs) or NoC components integrated within the FPGA fabric. This NoC interconnect augments the existing FPGA interconnect. In one embodiment, the NoC is used as system-level interconnect to connect compute and communication modules to one another and integrate large systems on the FPGA. The NoC components include a “fabric port”, which is a configurable interface that bridges both data width and frequency between the embedded NoC routers and the FPGA fabric components such as logic blocks, block memory, multipliers, processors or I/Os. Finally, the FPGA design flow is modified to target the embedded NoC components either manually through designer intervention, or automatically.

### FIELD OF THE INVENTION

The invention relates to Field-Programmable Gate-Arrays (FPGAs) or other programmable logic devices (PLDs) or other devices based thereon. Specifically, the addition of networks-on-chip (NoC) to FPGAs. This includes both modifications to the FPGA architecture and design flow.

### BACKGROUND

This invention relates to FPGAs and more particularly to a new interconnect architecture for such devices.

FPGAs are a widely-used form of integrated circuit due to the flexibility provided by their customizable nature. FPGAs consist primarily of programmable logic blocks, programmable inputs and outputs (I/Os) and programmable interconnect. Traditionally, logic blocks are organized into a 2 dimensional array and these logic blocks are surrounded by programmable interconnect wires and multiplexers.

An FPGA's programmable logic blocks traditionally consist of a plurality of lookup tables, multiplexers and flip flops or latches. Lookup tables typically consist of small digital memories that can be programmed to implement any logic functions of a certain size.

An FPGA's programmable interconnect consists primarily of different-length wires and programmable multiplexers. By connecting multiple wires using programmable multiplexers, different length connections can be created between any two logic blocks or I/Os.

As FPGAs become larger, larger specialized blocks are implemented on FPGAs to improve efficiency. These blocks are referred to as hard blocks. Examples of hard blocks include block random-access memory (BRAM), multiplication units or complete processor cores. These hard blocks are also connected to one another and to logic blocks and I/Os on an FPGA using the current programmable interconnect.

Additionally, modern FPGAs include dedicated I/O controllers and interfaces such as memory controllers or high-speed transceivers such as peripheral component interconnect express (PCIe) or gigabit Ethernet. Currently these I/O controllers are connected to blocks on the FPGA through the existing programmable interconnect.

The plurality of the described components on an FPGA can be programmed to implement an unlimited number of different digital circuits by programming some or all of the FPGA blocks and connecting them together in different ways.

Computer-aided design (CAD) tools assist in the design of digital circuits on FPGAs and specifically, they translate a human-readable representation of a design into a machine-readable one. Additionally, system-design CAD tools aid designers of FPGA systems by automatically generating the interconnect that connects modules in a design as opposed to the manual design of this interconnect by a designer. Examples of such tools by FPGA vendors include Altera Qsys and Xilinx EDK.

### SUMMARY OF THE INVENTION

According to the invention, an FPGA incorporates one or more programmable NoCs or NoC components integrated within the FPGA fabric. This NoC interconnect does not replace any aspect of existing FPGA interconnect that is described in prior work; rather, it augments the existing FPGA interconnect. In one embodiment, the NoC is used as system-level interconnect to connect compute and communication modules to one another and integrate large systems on the FPGA. The FPGA design flow is altered to target the NoC components either manually through designer intervention, or automatically. The computation and communication modules may be either constructed out of the FPGA's logic blocks, block RAM modules, multipliers, processor cores, I/O controllers, I/O ports or any other computation or communication modules that can be found on FPGAs or heterogeneous devices based thereon.

The NoC or NoCs added to the FPGA consist of routers and links, and optionally fabric ports. Routers refer to any circuitry that switches and optionally buffers data from one port to another. NoC routers may consist of, but are not limited to, any of the following: crossbars, buffered crossbars, circuit-switched routers or packet-switched routers. Links are the connections between routers. In one embodiment NoC links are constructed out of the conventional FPGA interconnect consisting of different-length wire segments and multiplexers. In another embodiment, NoC links consist of dedicated metal wiring between two router ports. Both embodiments of the NoC links may include buffers or pipeline registers. The fabric port connects the NoC to the FPGA fabric and thus performs two key bridging functions. The first function of the fabric port is width adaptation between the computation or communication module and the NoC. In one embodiment, this is implemented as a multiplexer, a demultiplexer and a counter to perform time-domain multiplexing (TDM) and demultiplexing. The second function is clock-domain crossing; in one embodiment this is implemented as an asynchronous first-in first-out (FIFO) queue. Although the NoC targets digital electronic systems, all or parts of the presented NoC can be replaced using an optical network on chip. The NoC can also be implemented on a separate die in a 3D die stack.

Changes to the FPGA design flow to target NoCs may be divided into two categories; logical design and physical design. The logical design step concerns the functional design of the implemented system. In the logical design step all or part of the designed system is made latency-insensitive by adding wrappers to the modules. The logical design step also includes generating the required interfaces to connect modules to an NoC and programming the NoC for use. Programming the NoC includes, but is not limited to the following: configuring the routers, assigning priorities to data classes, assigning virtual channels to data classes and specifying the routes taken through the NoC. The physical design flow then implements the output of the logical design step on physical circuitry. It include mapping computation and communication modules to NoC routers, and floorplanning the mentioned modules onto the FPGA device. Together, these architecture and design flow changes due to the addition of NoCs to FPGAs will raise the level of abstraction of system-level communication, making design integration of large systems simpler and more automated and making system-level interconnect more efficient.

### BRIEF DESCRIPTION OF THE DRAWINGS

For the purpose of explanation, some aspects of the invention and exemplary embodiments are illustrated by the drawings; however, they do not constitute the entirety of this invention.

FIG. 1 shows an FPGA chip with an exemplary NoC topology and some details of the connection between NoC routers and FPGA compute modules.

FIG. 2A and FIG. 2B illustrate exemplary floorplans of an NoC on the FPGA. FIG. 2A highlights the router interface to soft NoC links while FIG. 2B the router interface to hard NoC links.

FIG. 3A and FIG. 3B show exemplary embodiments of two alternative implementations of NoC links; soft and hard links respectively.

FIG. 4 shows exemplary NoC topologies.

FIG. 5 is a block diagram of an exemplary NoC router embodiment.

FIG. 6 shows one embodiment of a fabric port.

FIG. 7 is a flow chart depicting one embodiment of a modified FPGA design flow to target enhanced FPGAs with NoCs.

### DETAILED DESCRIPTION OF THE INVENTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

For example, the apparatus and techniques of the present invention will be described in the context of FPGAs. However, it should be noted that the techniques of the present invention can be applied to other programmable chips similar to FPGAs or based on them. In the following description, numerous specific details are set forth in order to provide a thorough understanding of the present invention. The present invention may be practiced without some or all of these specific details. In other instances, well known process operations have not been described in detail in order not to unnecessarily obscure the present invention. While the present invention is currently targeting silicon-based devices, the ideas, claims and innovations disclosed here may apply to future non-silicon devices without departing from the spirit or scope of the invention. For example, optical NoCs may be used instead of transistor and wire based implementations.

Various techniques and mechanisms of the present invention will sometimes be described in singular form for clarity. However, it should be noted that some embodiments include multiple iterations of a technique or multiple instantiations of a mechanism unless noted otherwise. For example, an NoC is used in a variety of contexts. However, it will be appreciated that multiple NoCs can also be used while remaining within the scope of the present invention unless otherwise noted. Furthermore, the techniques and mechanisms of the present invention will sometimes describe two entities as being connected. It should be noted that a connection between two entities does not necessarily mean a direct, unimpeded connection, as a variety of other entities may reside between the two entities. For example, a router port may be connected to another router port using soft interconnect which implies the use of some form of programmable multiplexers and possibly pipeline registers on the path of the connection. Consequently, a connection does not necessarily mean a direct, unimpeded metal link unless otherwise noted.

### OVERVIEW OF THE INVENTION

The present disclosure involves an innovative FPGA architecture. An NoC is partially or fully embedded on the FPGA to augment the programmable interconnect available on chip. The NoC contains wide groups of wires that are henceforth referred to as links, and switching elements henceforth referred to as routers and an interface between the NoC router port and the FPGA fabric henceforth referred to as a fabric port. The routers, links and fabric ports, or a subset of the presently mentioned elements may constitute an NoC. The NoC functionality is to switch and transport data from one part of the FPGA to another. The NoC may be connected to a subset or to all of the following computation modules: the FPGA fabric referring to logic blocks and programmable interconnect traditionally found on FPGAs, memory modules, digital signal processors (DSPs), central processing units (CPUs) and other computation modules that are used on FPGAs but not mentioned herein. The NoC may also connect to a subset or all of the following communication modules: I/O buffers, memory interfaces such as double data rate (DDR) memory controllers, transceivers such as peripheral component interconnect express (PCIe) controllers and Ethernet interfaces, and other FPGA I/O interfaces or controllers not mentioned herein.

The FPGA architecture may or may not be modified to accommodate the addition of the NoC. To accommodate for the area required by the NoC, only a small fraction of the logic elements and interconnect must be removed from the FPGA without any architectural changes to existing FPGA elements.

Some or all of the NoC components may be embedded on the FPGA out of hard logic. This refers to the implementation of NoC components as hard logic using standard-cell design or custom logic design, or a mixture of the two methodologies. Some components may be implemented out of soft logic. This refers to configuring the FPGA fabric to perform one of the functions of the NoC. For example, the NoC routers may be embedded as hard logic to increase performance and improve efficiency, while the fabric port is partially constructed out of soft logic to suit application needs.

The presently mentioned implementation options also apply to NoC links. Hard NoC links refer to connections between routers that are only capable of connecting two router ports; these would be implemented using interconnect drivers and metal wires. Soft NoC links instead construct the NoC links out of the FPGA fabric interconnect. The FPGA fabric interconnect consists of wire segments, drivers and multiplexers and has the ability to change the connection length, direction and endpoints based on a programmed configuration. Both hard and soft NoC links are particular and important exemplary embodiments of NoC links. However, NoC links implementations may deviate from the mentioned embodiments.

Of particular importance are two NoC embodiments. The first NoC embodiment is implemented completely out of hard logic. This means that the routers, links, and the fabric ports are all embedded on the FPGA. This NoC is henceforth referred to as a hard NoC. The second important NoC embodiment consists of hard routers, hard fabric ports and soft links. This is henceforth referred to as a mixed NoC. Note that the fabric port in both the mixed and hard NoCs can be extended using soft logic to implement additional functionality. Hard and mixed NoCs are only two specific embodiments of NoCs on FPGAs and this invention is not limited to them; however, this disclosure will focus on their implementation details. All ideas, claims and details disclosed pertaining to hard and mixed NoCs may apply to other NoC implementations on programmable devices without departing from the scope or spirit of the invention.

Both hard and mixed NoCs have benefits to FPGA devices and they exhibit different tradeoffs. Hard NoCs have higher area and power efficiency, and better performance in terms of clock speed when compared to mixed NoCs. This is because hard links are more efficient and can run faster than soft links. However, soft links are flexible as they can make arbitrary connections on the FPGA and thus allow designers to change the NoC topology on the FPGA device After FPGA fabrication, via reprogramming the interconnect forming the soft links.

In one embodiment, the NoC routers and links run at the same clock frequency while the fabric port crosses the NoC clock domain to the module clock domain. On the router side, the fabric port runs at the NoC clock frequency and on the module side, the fabric port runs at the module clock frequency. There is a speed mismatch between the FPGA fabric and an NoC. The FPGA fabric typically uses multiple relatively slow clocks, while the NoC runs on a single very fast clock. To use the NoC to efficiently connect FPGA fabric modules running at different speeds, the NoC frequency is fixed to its maximum speed and uses the fabric port to match the fabric bandwidth to the NoC bandwidth. The FPGA fabric achieves high computation bandwidth by using wide datapaths at low speeds, while the NoC is faster and can have a smaller data width. This is why both TDM logic and a clock crossing FIFO are required in fabric ports. The dual-port FIFO is required to maintain the freedom of optimizing the fabric frequencies independently from the NoC frequency; that is, the NoC frequency need not be a multiple of the fabric frequency or vice versa. This embodiment optimizes efficiency and performance, however other embodiments may also be possible; for instance, NoC links may run faster than the NoC routers.

The design flow or CAD flow of a traditional FPGA must not be altered to target an enhanced FPGA with an augmented NoC. NoC components can be instantiated within the description of a design similarly to any other block that exists on the FPGA thus allowing the manual connection and programming of embedded NoCs on FPGAs. However, more design flow automation is possible in an enhanced design flow tailored to target embedded NoCs on FPGAs. For instance, an enhanced design flow may automatically prepare design modules to interface to an embedded NoC, interface the design modules to NoC routers according to communication requirements and program the embedded NoC to move data according to the configured design. The design flow changes required for the proposed enhanced design flow are subdivided into two types of changes: logical design and physical design. The logical design flow concerns mainly with the system circuitry and design and has little or no knowledge of the FPGA device on which it is implemented. Logical design flow is sometimes referred to as system-level design and may be specified using high-level programming languages such as C, Java or OpenCL to boost productivity. The physical design flow refers to what is considered the traditional digital design flow for FPGAs. Physical design may start with a hardware description language such as Verilog, then synthesis translates the specification to FPGA blocks, then placement and routing map the synthesized blocks onto an FPGA device and connects them using the FPGA interconnect. Logical design flow and physical design flow are terms that will be used in this disclosure to refer to the presently mentioned definition.

Modifications to the logical design flow include changing that design flow to target hard and mixed NoCs instead of targeting soft bus-based NoCs for system-level interconnect as is traditionally done. In one embodiment, both the designed system and the NoC interconnect are specified by the user or system designer, and the NoC is programmed manually by the user to perform the desired operation. The logical and physical design flows are only modified to include the NoC components in their design libraries.

In another embodiment, the user only specifies the computation and communication modules, and how they are connected together. The connections between modules may be specified as latency-insensitive connections, meaning that latency variation on these links does not affect system functionality. The specified connections, whether they are latency sensitive or latency insensitive, describe connections that are to be mapped onto the NoC routers and links, or other interconnection types. The system modules are connected to NoC routers to be able to communicate through the NoC, but may also connect using other forms of interconnect to other modules.

In the presently mentioned disclosure, modifications to the logical design flow may include steps to do the following tasks on part or all of the system being designed:
The designer may tag the latency insensitive links with bandwidth requirements. These bandwidth estimates may also be automatically inferred from system-level simulations or other methods.
Modules are encapsulated with latency-insensitive wrappers to make the computation or communication module patient. This means that the module can tolerate extra cycles of latency on its inputs and outputs.
Any required NoC-unrelated logic is generated to allow system interconnection. This includes any bus-based interconnect between modules as in traditional system-level design tools.
Any required NoC-related logic is generated: this may include extra fabric port logic or NoC interfaces. This task should generate any logic necessary to interconnect the designed system partially or fully using an embedded NoC on the FPGA and is not limited to the mentioned examples.
Any required NoC programming may be done in the logical design step. This prepares an NoC for use with the system. For instance, NoC programming includes assigning addresses to modules and specifying routes between modules by programming routing tables in each NoC router. This task should prepare an NoC to transfer data between modules and may include more subtasks than those presently mentioned.

In the presently mentioned disclosure, modifications to the physical design flow may include steps to do the following tasks on part or all of the system being designed:
Programming the NoC topology by configuring the soft links where applicable.
Mapping module interfaces to NoC routers and latency-insensitive connections to direct or indirect NoC links. This task is done with reference to any bandwidth values annotated on the system.
Floorplanning or coarse placement of computation and communication modules, where applicable, with physical awareness of NoC router positions.

The presently mentioned design flow modifications refer to a particular embodiment. Other design flow modifications may be necessary in either logical or physical design. Further, logical and physical design flow tasks may be merged or may belong to another design flow step. For instance, if physical design information is known during logical design, mapping of module interfaces to NoC routers may be done earlier. Any design flow that refers to using an enhanced FPGA with an embedded NoC is claimed in this invention disclosure.

### BENEFITS OF THE INVENTION

The present invention as described has many benefits to FPGAs and heterogeneous programmable devices alike. As FPGAs integrate a more diverse set of computation and communication elements it becomes necessary to devise a higher-level protocol and interconnection architecture to connect large systems. This higher level of abstraction is attained through the presented NoC architecture and the described design flow modifications. The NoC is designed with the FPGA bandwidth requirements taken into account, especially the bandwidth generated at high-bandwidth I/Os such as transceivers and memory controllers. This greatly simplifies timing closure in designs that include these I/Os as their timing requirements are pre-built into the NoC. There is no longer a need to wait until after placing and routing the system-level interconnect to check whether the timing requirements have been met; rather, the NoC timing properties are already known a priori and these timing properties were designed to meet I/O requirements. This moves much of the timing closure problem from the FPGA user to the FPGA architect. The presented latency-insensitive design methodology eases timing closure as the number of cycles to transfer data between two modules can be varied without changing the functionality of the system. Further, latency-insensitive design eliminates the need for time-consuming compile-analyze-repipeline iterations. Both the use of an NoC and latency-insensitive design encourages modular design. The designed modules are timing-disjoint and only need to connect to an NoC interface to access the entirety of the FPGA; this allows easier parallel compilation and partial reconfiguration. Parallel compilation becomes simpler because there are no timing paths going between modules. Partial reconfiguration can be done by simply swapping out a module and replacing it with the partially-reconfigured module; if connected to an NoC interface, the partially-reconfigured module will have access to the whole system on the FPGA without the need for placement and routing of the interconnect pertaining to a partially-reconfigured module which may be a complex task in an already functioning FPGA. Another advantage is that compilation will innately become faster because the NoC interconnect is mostly pre-implemented and requires much fewer configuration bits than conventional interconnection structures on FPGAs.

Another benefit of using embedded NoCs on the FPGA is an improvement to the interconnect efficiency. NoCs reduce metal usage and metal area as data is naturally time-multiplexed on NoC links. Because the proposed NoCs are partially or fully embedded on the FPGA, they reduce power consumption for shared/arbitrated resources as all of the switching occurs in hard (embedded) logic, instead of soft logic created out of the FPGA fabric. Importantly, the NoC increases the FPGA on-chip communication bandwidth. This is a major advantage, as the high speed of modern transceivers and memory interfaces produce very high bandwidth data than can be challenging to transport across the FPGA. An NoC helps overcome the gap between logic speed scalability and metal speed scalability. Logic speeds are increasing more than metal speeds, presenting increasing timing closure challenges for long distance communication. An NoC requires a change of design style to latency-insensitive design, which can tolerate arbitrary latency on links. This naturally mitigates the problem of relatively long delays for communication.

The NoC abstraction will ease integrating FPGAs with other devices on the same die such as processors, DSPs, GPUs, or any other device to create new SoCs. The NoC allows access to many points in the soft logic at a higher abstraction level, making the FPGA fabric much more usable by the other elements of an SoC. Since modules can tolerate arbitrary latency on NoC links, connecting multiple chips can be transparent from a user's perspective. The connection can be made through two packaged chips, on a silicon interposer, or on a stacked die.

### DETAILED DESCRIPTION OF THE DRAWINGS

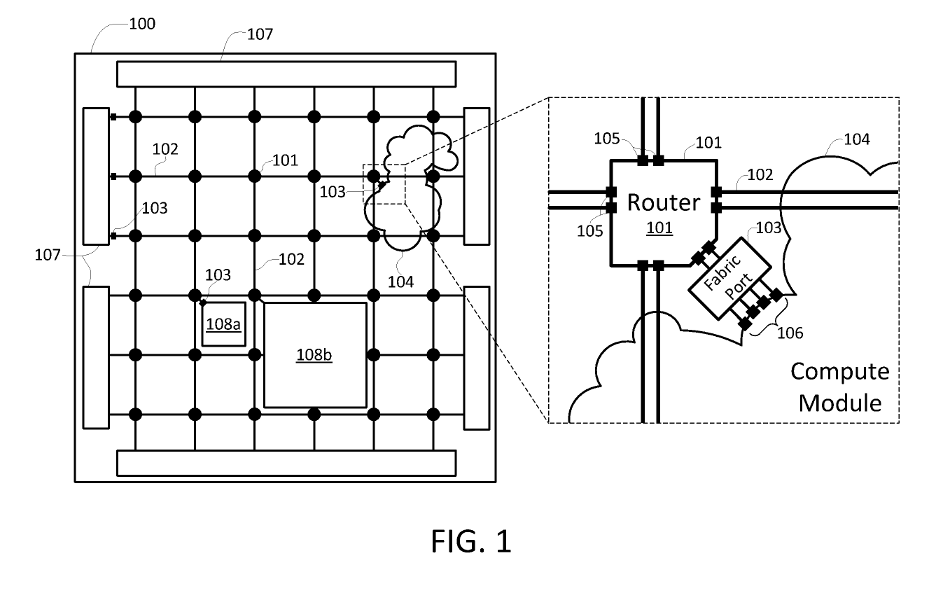

FIG. 1 shows an FPGA device 100 with an exemplary NoC topology. In this embodiment there is one NoC with an irregular topology that spans the entire FPGA. Various other embodiments may have one or more NoCs with either regular or irregular topologies. The NoC consists of routers 101, links 102 and fabric ports 103. Routers may consist of any switching element such as packet-switched routers, circuit-switched routers, crossbars and other components that may switch data. Links are the connections between routers and they may be either direct or indirect connections, and they may be either programmable or fixed.

The fabric port is a component that bridges the NoC clock domain and data rates to the FPGA fabric domain. The function of the fabric port is to cross clock domains and adapt the data width between the NoC routers and any connected compute module 104, hard blocks 108a and 108b or I/O interface 107. When the compute module 104 is configured out of the FPGA fabric, it is often running at a slower clock frequency and a wider data width compared to the NoC. In the presently mentioned case, the router ports 105 have a smaller data width than the compute module ports 106; however this is not required to be the case.

The compute module 104 consists of one or more FPGA elements. This includes logic blocks, memory modules, adders, multipliers and other elements that may be found on the FPGA for data computation or storage. The size of the compute module is arbitrary and is not limited by the NoC. Hard blocks 108a and 108b are larger elements that are implemented on FPGAs such as embedded processor cores or large memory blocks. The routers and fabric ports connected to hard blocks may be different than those connected to compute modules. Additionally large hard blocks 108b may interrupt the NoC topology.

The I/O communication modules 107 may either be direct I/O buffers that connect the FPGA core to I/O pins, or I/O interfaces or controllers that manipulate data before sending it through FPGA I/Os. An example of I/O standards is the low voltage differential signalling (LVDS) standard. Examples of I/O controllers include Ethernet media access control (MAC), DDR memory controllers and PCIe controllers. Note that the NoC may connect to any I/O interface, standard or controller found on the FPGA, and is not limited to the examples mentioned presently. A fabric port 103 may be used to connect to an I/O interface to bridge the clock and width differences between the NoC and the I/O communication module. This fabric port need not be identical to a fabric port used between the NoC and the FPGA fabric compute modules; in fact, it is likely that it will be different. Any module may connect to the NoC using one or more routers.

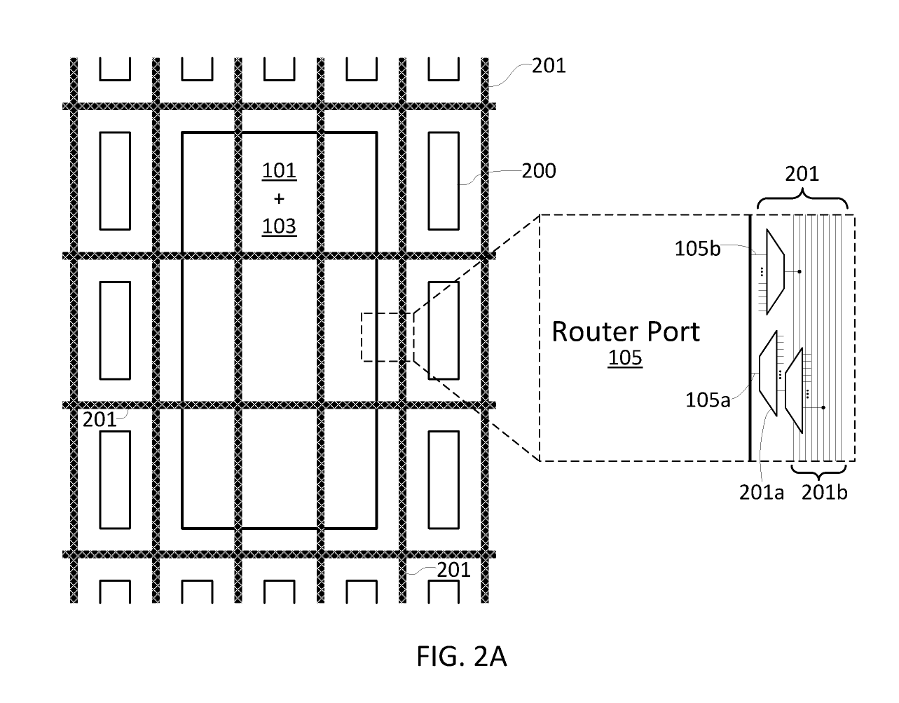

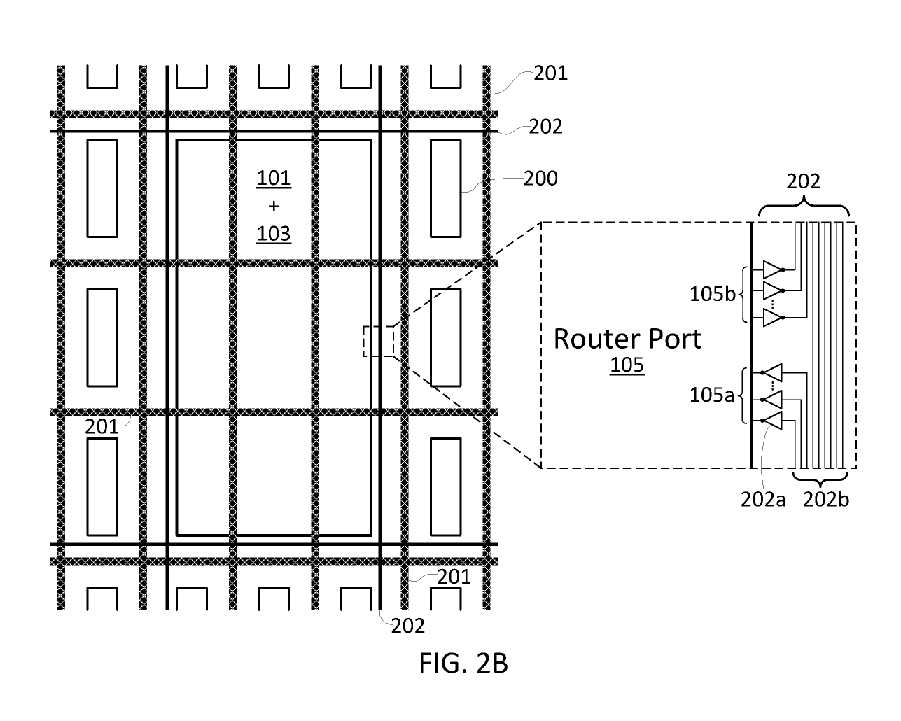

FIG. 2A and FIG. 2B illustrate exemplary floorplans of an NoC router 101 and fabric port 103 within the FPGA fabric. The routers are shown surrounded by logic blocks 200. While this is the most likely scenario, routers need not be surrounded by FPGA logic blocks and may be surrounded by any other element present on FPGAs. The size and aspect ratios in the presently mentioned figures, while realistic, are only examples and may be different. The two figures highlight the difference between two alternative embodiments of the NoC links.

FIG. 2A shows a router in a mixed NoC, with links that are constructed out of the existing FPGA interconnect 201. The router port 105 describes the part of the router that connects to the NoC links. A router input port 105a or output port 105b connects to wire segments 201b in the programmable interconnect 201 through programmable multiplexers 201a. In the example shown, one level of programmable multiplexers is shown at the output and two levels of multiplexers at each input. The mentioned multiplexer levels and count, and the sizes or properties shown in the drawing are only examples and may be different.

FIG. 2B shows additional dedicated wiring 202 that is added to the FPGA to implement hard NoC links. The router port 105 is connected to the metal wires 202b of the hard NoC links using interconnect drivers 202a. The metal wires are direct connections between two router ports, but may have drivers or pipeline registers on their path.

In both the mixed and hard NoC embodiments, the ports 106 connecting the fabric port to the FPGA fabric are connected to the programmable interconnect 201 in the same manner as the router ports of the mixed NoC in FIG. 2A. By connecting through the programmable interconnect, the fabric port uses the programmable FPGA interconnect to connect to any computation or communication module.

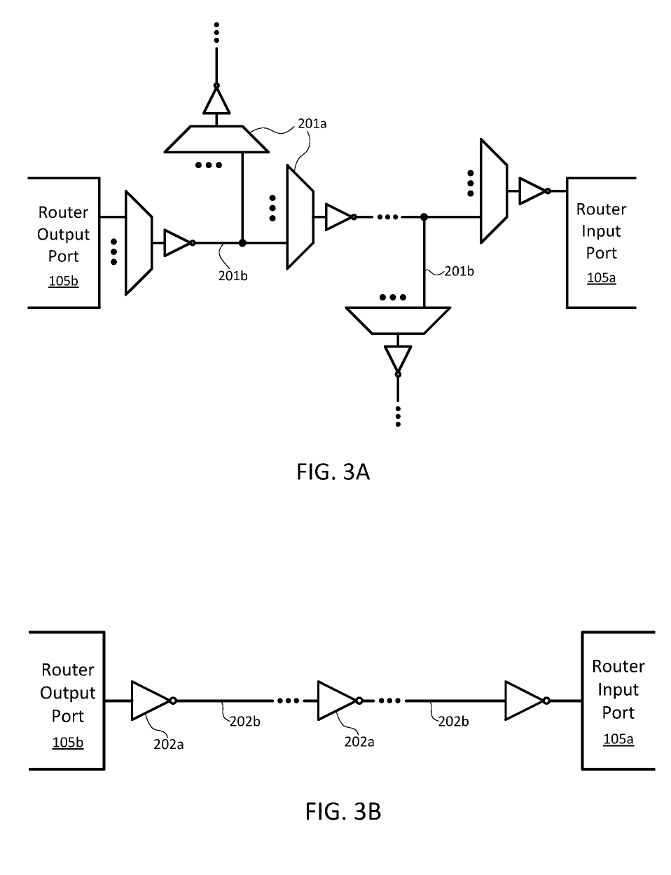

FIG. 3A and FIG. 3B show exemplary embodiments of two alternative implementations of NoC links. FIG. 3A shows an example indirect interconnect used to implement an NoC link between two router ports. The programmable FPGA interconnect is an indirect interconnect constructed out of wire segments 201b and multiplexers 201a. The programmable multiplexers may connect any horizontal wires to vertical wires or vice versa; this allows the formation of different topologies in mixed NoCs that utilize indirect programmable interconnect for their NoC links. We call such links soft links.

FIG. 3B shows an example of dedicated wiring implementing a direct connection between two routers. Interconnect drivers 202a and metal wires 202b implement the NoC link. The NoC link may also include other elements such as pipeline registers. We call such links hard links.

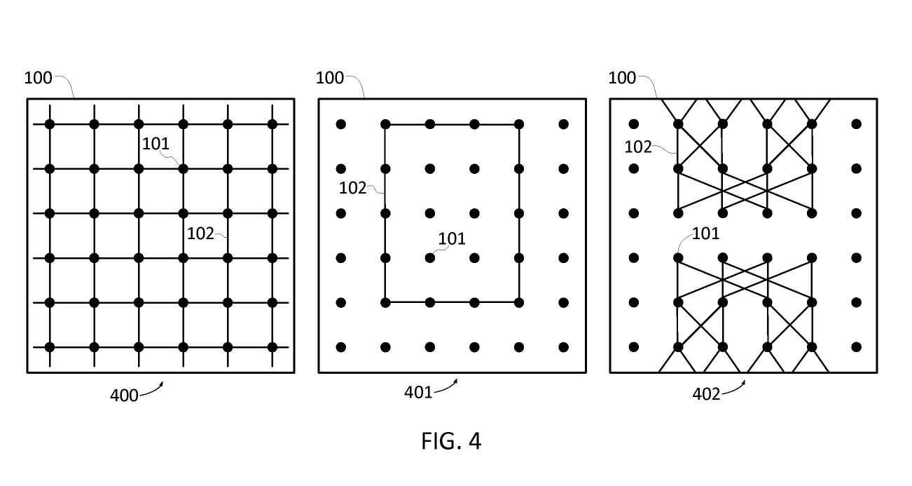

FIG. 4 depicts exemplary NoC topologies and highlights that not all routers must be used for the same NoC, or used at all in some embodiments. A hard NoC will likely implement topology 400 but may also be implemented as any other topology. However, the topology of the hard NoC will not be reconfigurable as the hard NoC links are static. A mixed NoC may be reconfigured after the FPGA device is manufactured to implement any of topologies 400, 401, 402, or other NoC topologies that may be implemented using the routers and soft interconnect resources on FPGAs.

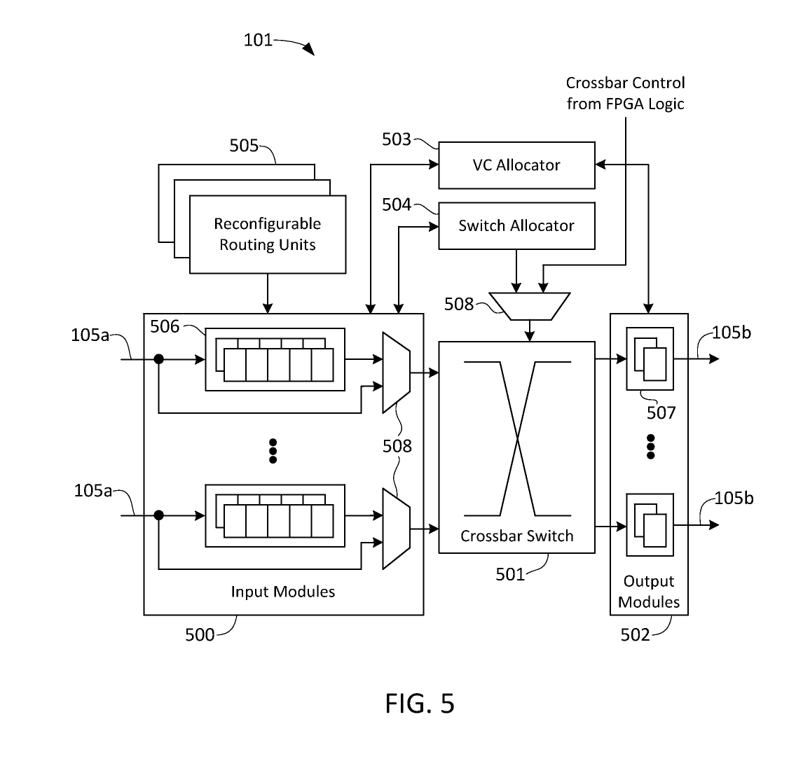

FIG. 5 is a block diagram of an exemplary NoC router embodiment. An NoC router contains circuitry operable to switch data from a router input port 105a to a router output port 105b. The router shown in FIG. 5 is a virtual-channel (VC) packet-switched router. It has 6 main components. Details of the implementation of each router component are omitted because these can be found in prior art and are not claimed as part of this invention.

Input modules 500 are the modules responsible for buffering data packets, often in a first-in first-out fashion. Data packets refer to units of data that are transported over an NoC. Data packets, or parts of data packets enter an NoC router through input ports 105a; subsequently, data enters into the input module buffers 506. The presently mentioned buffers are memory elements that are able to hold data for one or more clock cycles. Buffers 506 may be implemented using a combination of registers and logic gates or memory modules in some embodiments. For VC routers, the data buffers may be implemented as multi-queue buffers; one queue per virtual channel.

Traditionally, data remains in the input module until VC allocation, switch allocation and route computation are complete. A VC allocator 503 assigns the output virtual channel on which data will be transported. A VC allocator contains circuitry that takes requests for output VCs from all input virtual channels and arbitrate between them. One or more virtual channels may be granted for each data packet or data packet fragment that bids for output VCs. The assigned output VC will determine which VC queue will be used in the downstream router.

A switch allocator 504 takes requests to use the crossbar from all data packet fragments at the head of each input virtual channel. The switch allocator contains circuitry to arbitrate between the requests for crossbar resources and which grants access to the crossbar to all or some of the requesting data packet fragments.

Routing units 505 assign the path to the next router hop for data packets. Routing units contain circuitry to read packet information, decide on the appropriate route though the NoC, and append the computed route data to the data packet. In some embodiments routing units may be replicated for each input module buffer or queue for parallel operation. In this router embodiment, the routing units 505 are reconfigurable; meaning that they could be changed by reprogramming the FPGA or in some embodiments by the system running on the FPGA. This reconfigurability makes it possible to optimize the route computation based on the FPGA application traffic. Additionally, reconfigurable routing units are necessary in mixed NoCs where the topology is not known a priori.

Crossbar switch 501 contains circuitry to deliver data from one input port to one or more output ports.

Output modules 502 are optional components that may add pipeline registers 507 to the router output to enhance its clock frequency.

Bypass multiplexers 508 constitute a modification to traditional router designs. These bypass multiplexers allow the router to bypass the input modules and allocators to transform the router into a crossbar, or a buffered crossbar. A fast buffered crossbar will consist of crossbar 501 and output modules 502 with the crossbar control signals coming from the FPGA fabric instead of the allocators.

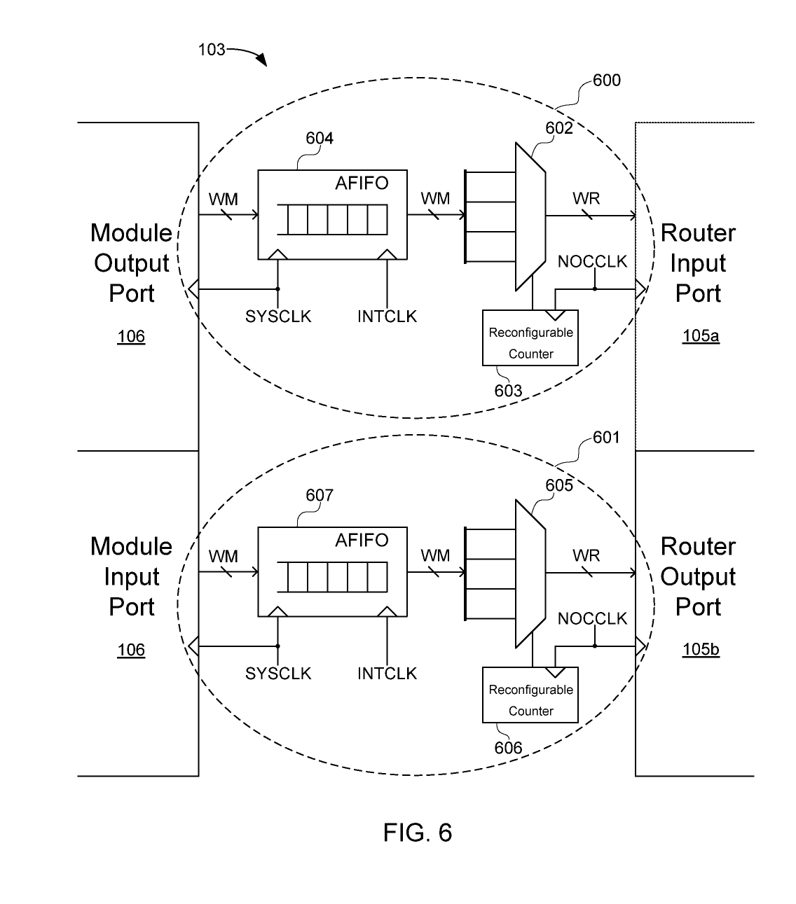

FIG. 6 shows one embodiment of a fabric port highlighting its two functions; clock-domain crossing and width adaptation. The fabric port contains circuitry operable to cross clock domains and adapt width between a computation/communication module on the FPGA and an NoC router port in both directions. The specific embodiment shown in FIG. 6 is only an exemplary implementation and the actual implementation may deviate from it. In the presently described drawing, the fabric port has two parts; a fabric port input 600 and a fabric port output 601. A fabric port input refers to the logic between a module output port 106 and a router input port 105a. A fabric port output refers to the logic between a module input port 106 and a router output port 105b.

The fabric port input 600 adapts the data from the module port 106 to the router input port 105a. The specific embodiment depicted in FIG. 6 adapts data signals of width WM and clock frequency SYSCLK on the module side to data width WR and clock frequency NOCCLK on the router side. In this embodiment SYSCLK and NOCCLK can be completely independent while the width WM must be equal to WR, 2*WR or 4*WR. This limitation is specific to the depicted embodiment. Multiplexer 602 and counter 603 constitute an exemplary implementation of TDM logic to adapt a wide data width to a narrower data width running at a higher clock speed. Counter 603 is configurable to perform either 4:1 TDM, 2:1 TDM or 1:1 data transfer through multiplexer 602. Asynchronous FIFO (AFIFO) 604 crosses clock domains between module clock SYSCLK and an intermediate clock INTCLK. NOCCLK is an integer multiple of INTCLK and is used in the read port of AFIFO 604. SYSCLK frequency does not depend on any other clock frequency and is used for writing data into AFIFO 604 at the same frequency at which the FPGA module operates.

The fabric port output 601 connects a router output port 105b to a module port 106 with a different data width and operating frequency. Demultiplexer 605 adapts data width from WR running with a clock frequency NOCCLK to WM running at a slower clock frequency INTCLK. In the mentioned embodiment, clocks NOCCLK should be a multiple of INTCLK, and they both should be phase aligned for proper operation. AFIFO 607 crosses clock domains from INTCLK to the FPGA module clock frequency SYSCLK.

Implementation details including read/write request signals for FIFO 604 are omitted for clarity; however, those skilled in the art should be familiar with their operation. In addition, flow control signals that are specific to the NoC implementation should also be included in the fabric ports to reflect buffer space availability at both the router and module.

Fabric port 600 may also include a protocol translator module which comprises logic that is necessary to translate from the data protocol used in the FPGA module to the data protocol used in the NoC. Example protocols include AMBA AXI which is a popular standard protocol used with many designs. In such a case, the translator module will decode the signals associated with the AMBA AXI protocol and translate the relevant signals into signals that are used by the NoC. Such protocol translators may either be implemented in soft logic or hard logic within the fabric port.

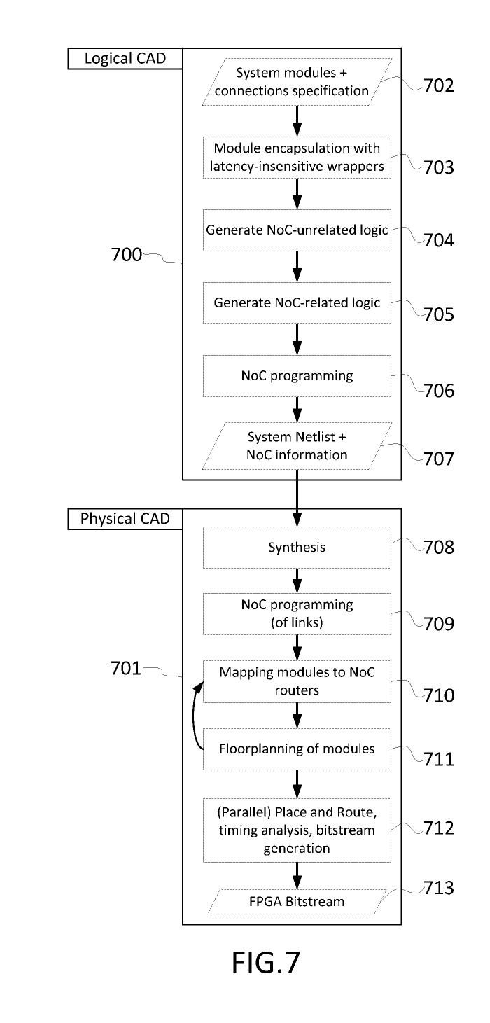

FIG. 7 shows one embodiment of a modified FPGA design flow for designing systems on an enhanced FPGA with an embedded NoC. The design flow is divided into logical computer-aided design (CAD) 700 and physical CAD 701. While physical CAD is necessary for compiling a design specification, logical CAD is not required and is used to improve productivity. Therefore, in the drawing, the logical CAD block may be partially or fully replaced with a manual system specification that might or might not use a hardware description language (HDL) and all or some of the logical CAD flow steps may be done manually. Further, if the logical CAD flow is used, manual intervention by the user may be done to guide compilation and improve results in any of the steps 702-706 and 709-712. In addition, performance evaluation or system or component simulation may be done at design representations 702, 707, 713 or other intermediate representations that are not shown in the diagram.

If the logical design flow were to be used, it starts with a system specification 702. This specification may be performed in any of the following, a mixture of the following, or other design unmentioned hardware specifications: HDL e.g. Verilog, higher-level languages e.g. OpenCL or Java, system design, or graphical tools e.g. Altera Qsys or Xilinx EDK or Mentor HDL Designer. System description 702 refers to a system with fully specified computation or communication modules but with unspecified or partially specified implementation of connections between system modules. Optionally, bandwidth or latency constraints, either automatically derived through simulation or manually annotated, may also be included in the system specification 702 to guide the subsequent CAD flow steps.

CAD step 703 encapsulates some or all of the system modules using latency-insensitive wrappers that make the modules patient. A patient module can tolerate variable latency on its inputs and outputs and may be stalled. Some modules may have already been designed to be patient by the module implementor and hence do not require latency insensitive wrappers be added to them in this step.

CAD step 704 generates any interconnect logic, interfaces, width adapters, clock-crossing logic, FIFOs or other necessary interconnect logic that implements system connections that are not implemented on the embedded NoC.

CAD step 705 generates any logic necessary to map system connections onto an embedded NoC. This may include interfaces, fabric ports or fabric port additions, additional NoC routers, FIFOs, or other logic necessary to connect any system module to the embedded NoC.

CAD step 706 programs the NoC components that are known thus far and appends information to program device-specific NoC components. Example elements that need to be programmed are the fabric port counters 603 and 606, routing units 505 and bypass multiplexers 508. Importantly, the module interfaces may also require programming in this step to assign an address for each component and program the logic that appends routing information to data, and creates data packets from module data before transmission over an NoC.

Description 707 contains a fully specified system with both the modules and the connection implementations specified or explicitly indicated that their implementation be later specified by a subsequent phase of the physical CAD flow.

CAD step 709 programs the NoC on the selected FPGA device. This includes programming the links if they are implemented soft and any other NoC elements that require programming before use. CAD step 709 may be repeated after step 710 if necessary.

CAD step 710 involves with mapping of system modules onto NoC nodes; that is, to decide which module or modules is/are connected to which router or routers. This step may be guided by bandwidth and latency constraints entered previously and may be implemented to reduce overhead, improve area/power efficiency or increase system performance.

CAD step 711 floorplans system modules onto the FPGA device. Synthesis 708 and place and route 712 refer to traditional FPGA CAD synthesis, place and route. Those skilled in the art should know how steps 708, 711 and 712 are performed. Description 713 refers to a well-known representation of designs that is used to configure FPGAs.

Iteration between design steps 710 and 711 may optionally be performed to ensure the router/module connections chosen and the module floorplan are consistent and optimized. A further optional flow reverses the order of steps 711 and 710 so the choice of the router to which a module connects is guided by the module floorplan.

The described CAD flow chart in FIG. 7 is an exemplary embodiment and may be modified or augmented with design steps to optimize the presented flow, or completely changed to better target NoC interconnect on FPGAs. Further, user intervention or manual design of certain components is possible at any of the design steps and should be allowed when designing the CAD tools.

### CLOSING REMARKS

While the invention has been particularly shown and described with reference to specific embodiments thereof, it will be understood by those skilled in the art that changes in the form and details of the disclosed embodiments may be made without departing from the spirit or scope of the invention. For example, a virtual-channel router was shown in the drawings but this may be replaced by a wormhole router, a circuit-switched router, a crossbar or any other switching element that is capable of performing the intended router function. It is therefore intended that the invention be interpreted to include all variations and equivalents that fall within the true spirit and scope of the present invention.

The embodiments of the invention in which an exclusive property or privilege is claimed are defined: Any combination of the described claims is also claimed as exclusive property.

1. An apparatus comprising networks-on-chip (NoCs) on a field-programmable gate array (FPGA) or related devices based thereon in which said NoC includes routers and links, and at least one of these components of the NoC is embedded in the device.

2. The apparatus of claim 1, wherein the NoC comprises routers, links and fabric ports.

3. The apparatus of claim 2, wherein the NoC is a mixed NoC in which routers and fabric ports are embedded hard circuitry and links are implemented using programmable interconnect.

4. The apparatus of claim 2, wherein the NoC is a hard NoC in which routers, fabric ports and links are all embedded on the FPGA in hard circuitry.

5. The apparatus of claim 2, wherein the routers are packet-switched routers.

6. The apparatus of claim 2, wherein the routers are configurable as packet-switched routers or buffered multiplexers.

7. The apparatus of claim 6, wherein the routers include multiplexers to bypass input buffers.

8. The apparatus of claim 6, wherein the routers include multiplexers to bypass switch allocators and feed control to the crossbar directly from the FPGA programmable logic.

9. The apparatus of claim 2, wherein the links contain pipeline registers.

10. The apparatus of claim 2, wherein the fabric port contains data width adaptation circuitry.

11. The apparatus of claim 2, wherein the fabric port contains clock-domain crossing circuitry.

12. The apparatus of claim 2, wherein the fabric port contains a translator unit to convert the NoC packets to the signals and data ordering of a standard IP interface.

13. A design method to extract the communication requirements of a digital system from the design description and implement a portion of said communication on an embedded network-on-chip (NoC) within a field-programmable gate array (FPGA), or related devices based thereon.

14. The design method of claim 13, further comprising steps to add digital circuitry to make design modules insensitive to latency.

15. The design method of claim 13, further comprising steps to add NoC components or NoC-related annotations to a digital design.

16. The design method of claim 13, further comprising a design step that configures an embedded NoC.

17. The design method of claim 13, further comprising a floorplanning step.

18. The design method of claim 13, wherein placement and routing of individual design modules within the system are performed in parallel.

19. The design method of claim 13, further comprising a step in which one or more translator units are inserted between one or more modules and the NoC.

20. A machine-readable medium having stored thereon sequences of instructions, the sequences of instructions including instructions which, when executed by a processor, causes the processor to perform: extracting the communication requirements of a digital system from the design description and implementing a portion of said communication on an embedded network-on-chip (NoC) within a field-programmable gate array (FPGA), or related devices based thereon.
